(19) United States
(12) Patent Application Publication
(10) Pub. No.: US 2017/0271536 A1
(43) Pub. Date: Sep. 21, 2017

(54) SYSTEM AND METHOD FOR CREATING A PATTERN ON A PHOTOVOLTAIC STRUCTURE

(71) Applicant: SolarCity Corporation, San Mateo, CA (US)

(72) Inventors: Christoph G. Erben, Los Gatos, CA (US); Zhi-Wen Sun, Sunnyvale, CA (US)

(73) Assignee: SolarCity Corporation, San Mateo, CA (US)

(21) Appl. No.: 15/072,200

(22) Filed: Mar. 16, 2016

(51) Int. Cl. H01L 31/0224; C23C 18/16

(52) U.S. Cl. CPC H01L 31/022433; C23C 18/1619; C23C 18/1689

(57) ABSTRACT

A system and method for fabricating a photovoltaic structure is provided. During fabrication, the system can apply a wax coating on at least one surface of a multilayer photovoltaic structure, the surface of the multilayer photovoltaic structure being electrically conductive. The system can then pattern the wax coating using one or more laser beams. The patterned wax coating includes a plurality of openings that expose portions of the electrically conductive surface of the multilayer photovoltaic structure.

### FIELD OF THE INVENTION

This is generally related to semiconductor device fabrication. More specifically, this is related to a system and method for creating a metallization pattern on photovoltaic structures.

### Definitions

A “solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

### BACKGROUND

The negative environmental impact of fossil fuels and their rising cost have resulted in a need for cleaner, cheaper alternative energy sources. Among different forms of alternative energy sources, solar power has been favored for its cleanness and wide availability.

A solar cell converts light into electricity using the photovoltaic effect. Most solar cells include one or more p-n junctions, which can include heterojunctions or homojunctions. In a solar cell, light is absorbed near the p-n junction and generates carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit. High efficiency solar cells are essential in reducing the cost of producing solar energy.

One important factor affecting the energy-conversion efficiency of a solar cell is its internal resistance. Reducing resistive loss can increase the energy outputted by the solar cell, and hence the solar cell's efficiency. It has been shown that electrode grids based on electroplated Cu have significantly lower resistivity than conventional screen-printed Ag grids. In addition to having lower resistivity, electroplated Cu grids also cost less than the Ag grids.

Conventional approaches for electroplating Cu grids typically can involve a photolithography process that defines the grid pattern, including finger lines and busbars. However, this approach has a number of drawbacks.

### SUMMARY

One embodiment can provide a system for fabricating a photovoltaic structure. During fabrication, the system can apply a wax coating on at least one surface of a multilayer photovoltaic structure, the surface of multilayer photovoltaic structure being electrically conductive. The system can then pattern the wax coating using one or more laser beams. The patterned wax coating includes a plurality of openings that can expose portions of the electrically conductive surface of the multilayer photovoltaic structure.

In a variation of this embodiment, the wax coating can be applied simultaneously on both surfaces of the multilayer photovoltaic structure.

In a variation of this embodiment, applying the wax coating can involve one of: placing the multilayer photovoltaic structure in a hot wax bath, applying a curtain-coating technique, and applying a spin-coating technique.

In a variation of this embodiment, a thickness of the wax coating can be between 100 and 500 microns.

In a variation of this embodiment, the laser beams can include one laser beam for creating openings corresponding to busbars and one laser beam for creating openings corresponding to finger lines. The laser beam that creates the busbar openings has a larger spot size that the laser beam that creates the finger line openings.

In a variation of this embodiment, patterning the wax coating can involve steering the laser beams using mirrors.

In a further variation, steering the laser beams can involve a galvanometer.

In a variation of this embodiment, the system can use the patterned wax coating as a plating mask to plate a metallic grid on the surface of the multilayer photovoltaic structure, the plated metallic grid corresponding to the openings in the wax coating.

In the further variation, subsequent to plating the metallic grid, the system can remove the patterned wax coating using hot water.

In a variation of this embodiment, the electrically conductive surface of the multilayer photovoltaic structure can include a metallic seed layer, and the metallic seed layer can be formed on a transparent conductive oxide layer using a physical vapor deposition technique.

### BRIEF DESCRIPTION OF THE FIGURES

FIG. 1 shows an exemplary photovoltaic structure with low-resistivity electrode.

FIG. 2 shows a conventional process for electroplating a Cu grid on the surface of a photovoltaic structure.

FIG. 3 shows an exemplary process for electroplating a metallic grid.

FIG. 4 shows an exemplary system for masking and plating photovoltaic structures.

FIG. 5A shows an exemplary laser-wax-patterning system.

FIG. 5B shows an exemplary laser-wax-patterning system.

FIG. 5C shows an exemplary laser-wax-patterning system.

FIG. 6A shows an exemplary grid pattern formed on the front surface of a photovoltaic structure.

FIG. 6B shows an exemplary grid pattern formed on the back surface of a photovoltaic structure.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention can provide a system and method for fabricating high-efficiency photovoltaic structures. More specifically, a system and method for electroplating a metallic grid on the surface(s) of photovoltaic structures is described. During fabrication, photovoltaic structures that have been processed and are ready for metallization are coated with a layer of wax. Laser beams, which can generate enough heat to melt the wax, can scan the wax-coated surface of the photovoltaic structures to create a grid pattern. More specifically, windows that expose the underlying metallic seed layer can be created in the wax layer. These windows correspond to locations of metal lines of the desired metallic grid, including busbars and finger lines. The photovoltaic structures can then be sent to an electroplating tool (e.g., a plating bath) for electroplating. After plating, the remaining wax can be removed. The fabrication can then be completed with the removal of exposed portions of the metallic seed layer.

### Fabrication Process

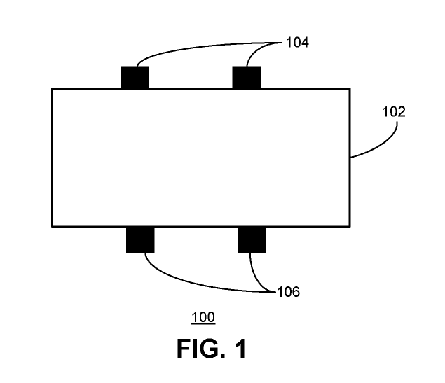

FIG. 1 shows an exemplary photovoltaic structure with low-resistivity electrode. In FIG. 1, photovoltaic structure 100 can include multilayer structure 102, and metallic grids 104 and 106. Multilayer structure 102 can include one or more semiconductor and/or dielectric layers for generating current. Multilayer structure 102 sometimes can also include transparent conductive oxide layers. Metallic grids 104 and 106 can be responsible for collecting the photo-generated current. Compared to screen-printed Ag grids, electroplated metallic grids (e.g., a Cu grid) typically can cost less and have lower serial resistance. A detailed description of the electroplated metallic grid can be found in U.S. patent application Ser. No. 12/835,670, entitled “Solar Cell with Metal Grid Fabricated by Electroplating,” filed Jul. 13, 2010, and U.S. patent application Ser. No. 13/220,532, entitled “Solar Cell with Electroplated Metal Grid,” filed Aug. 29, 2011, the disclosures of which are incorporated herein by reference in their entirety. Conventional approaches for electroplating metallic grids on photovoltaic structures often involve a photolithography process. More specifically, the grid pattern (e.g., at which locations will the metallic ions be deposited during plating) can be defined using a photolithography process.

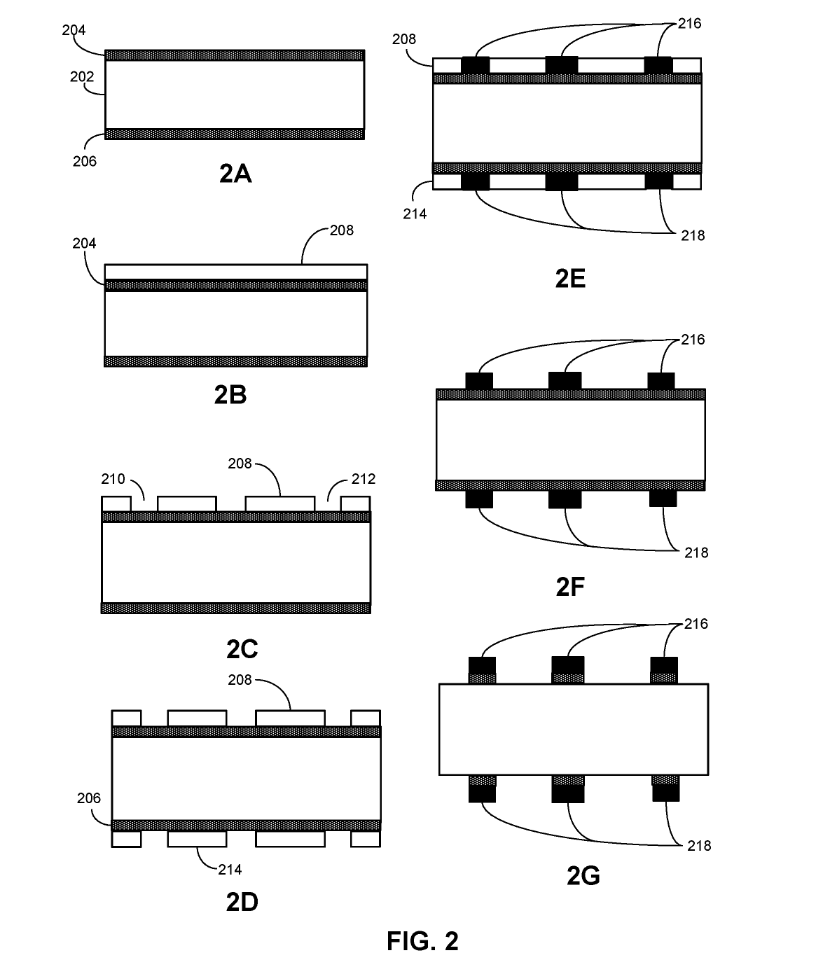

FIG. 2 shows a conventional process for electroplating a Cu grid on the surface of a photovoltaic structure. In operation 2A, a photovoltaic structure with all layers but the metallic grid is obtained. Depending on the design, the photovoltaic structure can have various layer structures. In the example shown in FIG. 2, the photovoltaic structure can include a semiconductor layer stack 202 and front and back conductive layers 204 and 206. The conductive layers can play an important role in the subsequent plating process.

In operation 2B, photoresist layer 208 can be formed on front conductive layer 204. Various approaches can be used to form photoresist layer 208. For mass production scenarios, forming photoresist layer 208 can involve applying (or laminating) a layer of dry-film resist on the surface of front conductive layer 204. In operation 2C, photoresist layer 208 can be patterned. More specifically, a number of windows (e.g., windows 210 and 212) can be formed within photoresist layer 208, partially exposing the underlying conductive layer 204. Locations of these windows can correspond to locations of the desired metallic grid lines. Standard photoresist exposure and developing procedures can be used to pattern photoresist layer 208.

In operation 2D, patterned photoresist layer 214 can be formed on back conductive layer 206 using a process similar to operations 2B and 2C. In operation 2E, the photovoltaic structure with patterned photoresist on both surfaces can be placed in an electroplating bath for electroplating of front and back metallic grids 216 and 218. Because photoresist is electrically insulating, only the openings within photoresist layers 208 and 214 are electrically conductive (by exposing the underlying conductive layer). As a result, metallic ions (e.g., Cu ions) can be selectively deposited into the openings to form front and back metallic grids 216 and 218.

In operation 2F, front and back photoresist layers can be removed (e.g., by using a photoresist stripper). If conductive layers 204 and 206 are non-transparent, operation 2G will be needed, where portions of conductive layers 204 and 206 that are not covered by the metallic grids are removed.

As one can see from FIG. 2, using photolithography to define the plating mask can involve multiple complicated procedures. For example, the deposition and exposure of the photoresist can only be done one side at a time. To pattern both sides, the photovoltaic structures need to be flipped over. This type of operation is usually undesired, because the photovoltaic structures are made of thin Si wafers and may be damaged when being flipped. Moreover, for mass production, the cost of the dry-film resist, including both the material cost and the cost for treating the photoresist waste, can become significant. Another drawback of this photoresist-based approach is the limited aspect ratio of the grid line, resulting from the limited thickness of the photoresist layer. Most dry-film resists are tens of microns thick, making it difficult to obtain a metallic grid line that can be 100 microns tall. The tall metallic grid can ensure low serial resistance while keeping the shading effect low. Although thicker resists may be possible, they can result in extended exposure time or incomplete exposure.

To reduce fabrication cost and to obtain grid lines with high aspect ratio, in some embodiments, instead of photoresist, wax can be used to create a plating mask. Compared with the photoresist-based plating mask, a wax-based plating mask can be cheap, reusable, and sufficiently thick.

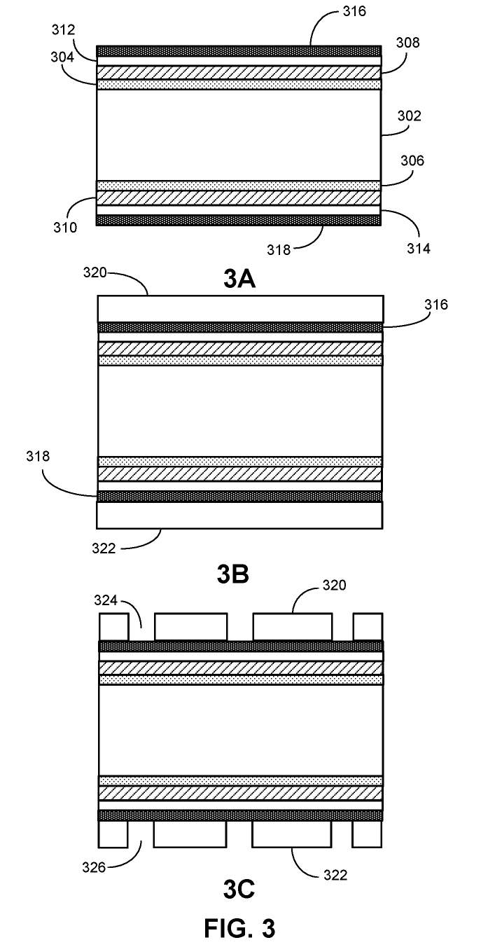

FIG. 3 shows an exemplary process for electroplating a metallic grid, according to an embodiment. In operation 3A, a photovoltaic structure with all layers but the metallic grid can be obtained. In some embodiments, the photovoltaic structure can include base layer 302, front and back passivation layers 304 and 306, surface-field layer 308, emitter layer 310, front and back TCO layers 312 and 314, and front and back metallic seed layers 316 and 318.

Substrate 302 can include a lightly doped or substantially intrinsic crystalline Si (c-Si) layer. Front and back passivation layers 304 and 306 can include wide bandgap materials (e.g., a-Si:H or SiNₓ:H) or dielectric materials (e.g., SiNₓ or SiOₓ). In some embodiments, front and back passivation layers 304 and 306 can each include a thin oxide layer that is formed using a wet oxidation technique (e.g., rinsing Si wafers under hot deionized water). Surface-field layer 308 can include a heavily doped amorphous Si (a-Si) layer. In some embodiments, surface-field layer 308 can face the majority of incident light, and hence can also be called the front surface-field (FSF) layer. If substrate 302 is doped with n-type dopants, FSF layer 308 can be doped with n-type dopants to act as an electron collector. Emitter layer 310 can include a heavily doped a-Si layer. For n-type doped substrate, emitter layer 310 can be doped with p-type dopants to act as a hole collector.

TCO layers 312 and 314 can include appropriate TCO materials that match the work function of surface-field layer 108 and emitter layer 110, respectively. For example, if emitter layer 110 is p-type doped, TCO layer 114 can include high work function TCO materials, e.g., TCO materials with a work function that is greater than 5.0 eV.

Front and back metallic seed layers 316 and 318 can include thin metallic layers that are directly deposited onto TCO layers 312 and 314, respectively, using a physical vapor deposition (PVD) technique (e.g., sputtering and evaporation). Their main function is to improve the adhesion between the subsequently plated metallic layer and the TCO layers.

In operation 3B, a wax layer can be deposited on front metallic seed layer 316 and back metallic seed layer 318, forming front wax layer 320 and back wax layer 322. Various types of wax materials can be used to form wax layers 320 and 322. In some embodiments, a low-temperature wax with a melting point between 50 and 70° C., preferably between 55 and 65° C., can be used to form the wax layers. Alternatively, a moderate-temperature wax with a melting point between 74 and 85° C. can also be used. A commonly used low-temperature wax can include petroleum-based microcrystalline wax. To ensure good absorption of the laser light, it can be preferable to select wax products having a darker (e.g., brown or black) color.

Various methods can be used to apply the wax onto the metallic seed layers. For example, the photovoltaic structures can be dipped into a container that contains melted wax. By controlling the temperature of the melted wax, one can control its viscosity, and hence the thickness of the wax coating. Alternatively, a curtain-coating technique can be used. For example, photovoltaic structures can be placed on a conveyor to go through a curtain of melted wax. In this scenario, the thickness of the wax coating can be controlled by controlling the conveyor speed and the temperature and flow rate of the wax. In addition to dip-coating and curtain-coating, it is also possible to use a spin-coating technique to coat the surfaces of the photovoltaic structures with wax. For spin-coating, the spin speed and the wax temperature can be configured to ensure the desired coating thickness is achieved. In some embodiments, the thickness of wax layers 320 and 322 can be between 100 and 500 microns.

In operation 3C, front and back wax layers 320 and 322 can be patterned, creating windows (e.g., windows 324 and 326) at locations corresponding to the desired grid lines. For high-precision and low-cost operations, direct laser writing can be used to create patterns in the wax layers. More specifically, one or more laser beams can scan the surface of the wax layers at pre-determined locations (e.g., at the desired finger line and busbar locations). Because wax has a low melting point, heat generated by the laser beam can evaporate the wax, exposing the underlying metallic seed layers. Therefore, by carefully arranging the path of the lasers, one can create a desired pattern on the wax layers. To ensure that wax at desired locations is completely removed without causing damage to the underlying layers, the power of the laser beams needs to be carefully controlled. In some embodiments, the power of each individual laser beam can be between 1 and 20 W, preferably between 10 and 15 W. Because the metallic seed layers can reflect laser lights, they can also facilitate the melting of the wax, making it possible to use lasers with a relatively low power to remove wax at desired locations.

The laser wavelength may not be a critical factor. To reduce cost and to enhance heat absorption by the wax, commercially available Class 4 green lasers (e.g., an Nd:YAG laser) can be used. The spot size (when focused onto the wax surface) of the laser beam may be critical to the feature size of the created pattern. In some embodiments, the desired width of the finger lines of the metallic grid can be between 20 and 100 microns. Accordingly, the focal spot of the laser beams can be configured (via the arrangement of a lens system) to be between 20 and 100 microns. Because the width of the busbars is significantly larger than the width of the finger lines, to create a window in the wax layer with a width matching that of the busbars, either a laser beam having a larger focal spot size is needed or a smaller laser beam needs to scan along the direction of the busbars multiple times. In some embodiments, front and back wax layers 324 and 326 can be patterned simultaneously. For example, the photovoltaic structure can be held vertically, and two or more sets of horizontal laser beams can scan both surfaces to create the patterns simultaneously. Alternatively, the photovoltaic structure can be placed horizontally on a transparent surface, and two or more sets of vertical laser beams (one from the top and one from the bottom) can scan both surfaces simultaneously. Alternatively, front and back wax layers 320 and 322 can be patterned in sequence.

In operation 3D, metallic materials can be deposited into the windows in the patterned wax layers 320 and 322 to form front and back metallic grids 328 and 330, respectively. More specifically, metallic materials can be deposited inside the windows of the patterned wax layers. In some embodiments, the photovoltaic structures can be placed inside an electroplating bath. Because wax is electrically insulating, only the windows/openings within wax layers 320 and 322 are electrically conductive (by exposing the underlying metallic seed layer). As a result, metallic ions (e.g., Cu ions) can be selectively deposited into the windows/openings to form front and back metallic grids 328 and 330.

In operation 3E, the pattered wax layers can be removed. Various techniques can be used to remove the wax. A simple method is to place the photovoltaic structures inside a hot water bath or rinse the photovoltaic structures using hot running water. This way, the wax will be melted by the hot water. After the hot water cools, the wax can re-solidify, and can be collected and re-used for creating plating masks.

In operation 3F, portions of metallic seed layers that are not covered by front and back metallic grids 328 and 330 can be removed. In some embodiments, they can be etched away using front and back metallic grids 328 and 330 as masks. For example, the photovoltaic structures can be dipped briefly inside an acidic solution (e.g., buffered HF acid), which can etch off metal. By controlling the etching time, one can ensure that exposed metallic seed layers are completely removed. Although such an etchant can also attack front and back metallic grids 328 and 330, because the metallic grids are much thicker than the metallic seed layers (e.g., 100 microns vs. 100 nm), the etching process does not significantly change the thickness of the metallic grids.

Compared with the conventional fabrication process shown in FIG. 2, the novel fabrication process shown in FIG. 3 has fewer steps, costs less (including both equipment and material cost), and can be environmentally friendly. In addition, because the wax plating mask can be much thicker than the photoresist plating mask, the resulting finger lines can have a much larger height-to-width aspect ratio (e.g., greater than 2).

### Fabrication System

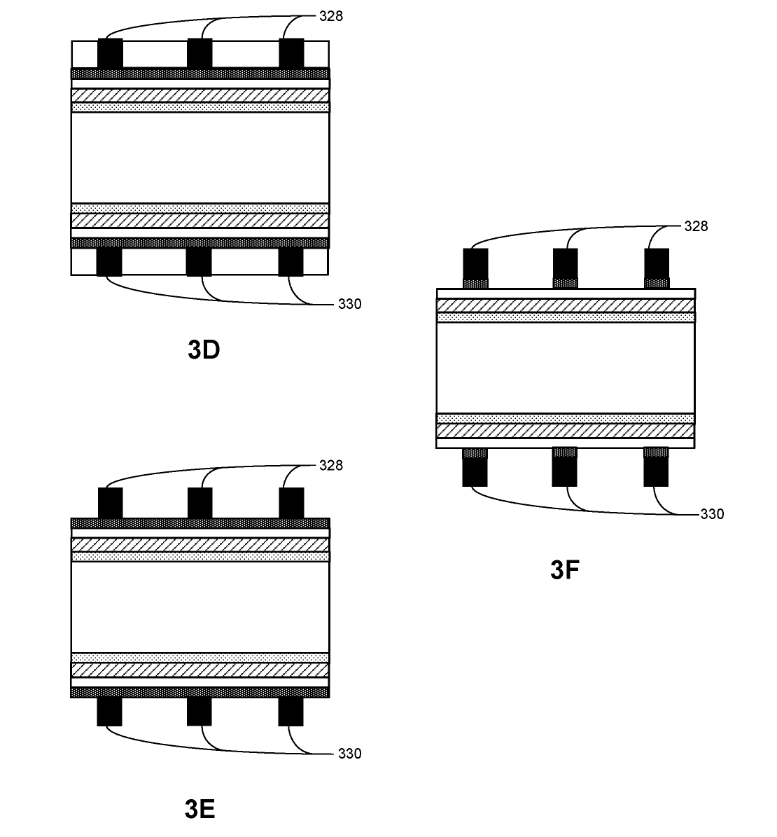

FIG. 4 shows an exemplary system for masking and plating photovoltaic structures, according to one embodiment of the present invention. Fabrication system 400 can include hot wax bath 402, cooling station 404, laser-wax-patterning station 406, electrolyte bath 408, rinsing station 410, and hot water bath 412.

Hot wax bath 402 can be a large heated tank that holds wax in the melting state. Photovoltaic structures that are ready for metallization can be dipped into hot wax bath 402 to obtain a wax coating on both surfaces. For example, a plurality of photovoltaic structures can be placed in a wafer-holding cassette, and a robotic arm can pick up the cassette and place the cassette into hot wax bath 402. By controlling the temperature of hot wax bath 402 and the time the wafer cassette spends in hot wax bath 402, one can control the thickness of the wax coating. In some embodiment, the thickness of the wax coating can be between 100 and 500 microns

After emerging from hot wax bath 402, the photovoltaic structures with the wax coating can be sent to cooling station 404 to cool down. More specifically, the wax coatings can solidify at cooling station 404. Subsequently, the photovoltaic structures can be transferred (e.g., by a conveyor system) to laser-wax-patterning station 406 for patterning of the wax coatings.

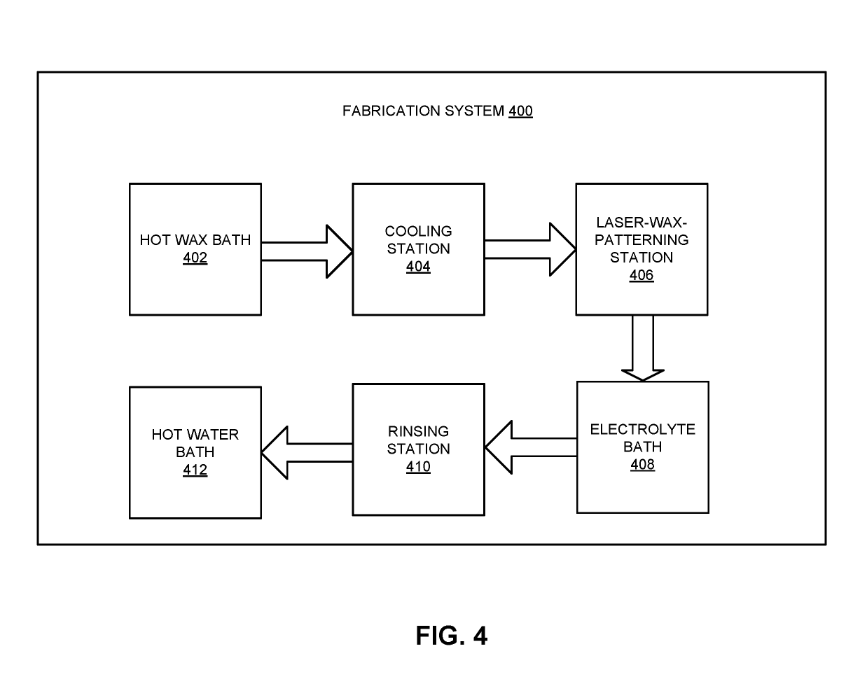

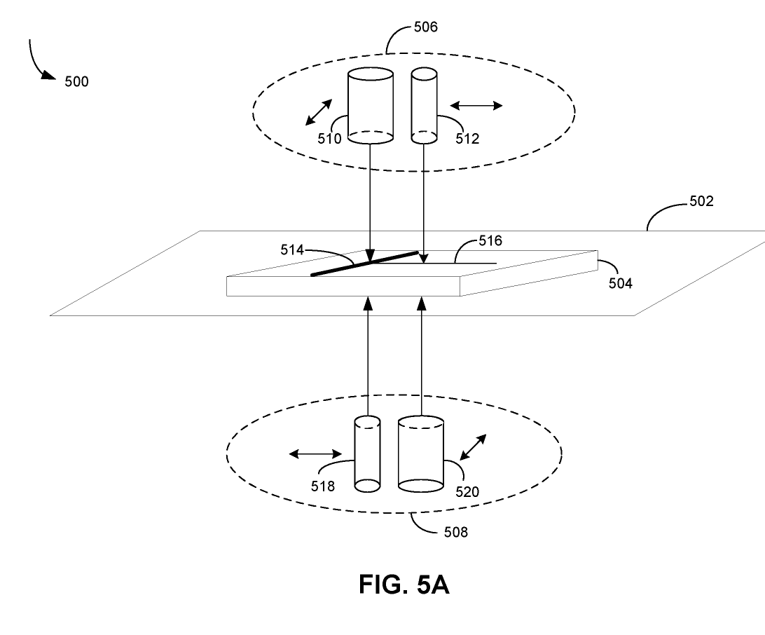

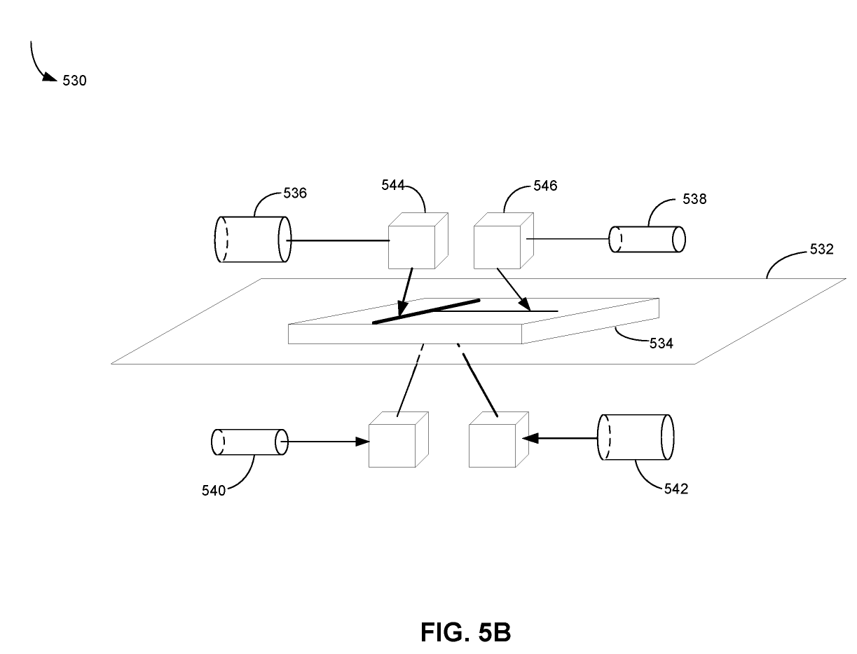

FIG. 5A shows an exemplary laser-wax-patterning system, according to an embodiment of the present invention. Laser-wax-patterning system 500 can include transparent platform 502 for supporting photovoltaic structures (e.g., photovoltaic structure 504), top laser set 506, and bottom laser set 508.

Transparent platform 502 can be made of transparent materials, such as glass, to allow laser beams to pass through. In some embodiments, transparent platform 502 can also include through holes or slots that can allow the escape of vaporized wax.

Top laser set 506 can include one or more lasers. More specifically, by shining laser beams onto the top wax layer, grooves/windows can be created on the top wax layer, because heat from the laser beam can evaporate the wax. In some embodiments, top laser set 506 can include at least a laser with a larger spot size (e.g., laser 510) and a laser with a smaller spot size (e.g., laser 512). Laser 510 can be used to create one or more windows (e.g., window 514) corresponding to the busbars in the top wax layer of photovoltaic structure 504. The spot size of laser 510 can be configured based on the width of the desired busbar pattern. For example, if the width of the desired busbar is about 800 microns, the diameter of the laser beam outputted by laser 510 can be configured (via a lens system that is not shown in FIG. 5) to be about 800 microns. To create the busbar pattern, in some embodiments, laser 510 can be moved, often via a robotic arm, along the direction of the busbars. If there are multiple busbars in the desired grid pattern, laser-wax-patterning system 500 can include multiple lasers with a larger spot size that can parallelly carve grooves on the top wax layer. Alternatively, one laser can be moved from one busbar location to the next to create the multiple busbar patterns.

Laser 512 can be used to create the windows (e.g., window 516) corresponding to the finger lines. Accordingly, the spot size of laser 512 can be configured based on the width of the desired finger line pattern. For example, if the width of the desired finger line is about 50 microns, the beam spot size of laser 512 can be configured to be about 50 microns. Because the finger lines typically are perpendicular to the busbars, to create the finger line patterns, the moving direction of laser 512 can be perpendicular to that of laser 510. A typical grid pattern can include many (e.g., tens of) finger lines. Hence, for high system throughput, multiple laser beams can be used to create the finger lines. The multiple laser beams can be achieved via the application of a laser array or one or more beam splitters that can split a single laser output into multiple beams.

Similar to top laser set 506, bottom laser set 508 can include one or more lasers (e.g., laser 518 and 520) for creating grooves/windows on the bottom wax layer of the photovoltaic structures. The lasers can be configured (including the power, location, and movement pattern) based on the desired grid pattern on the corresponding surface of the photovoltaic structures. Top laser set 506 and bottom laser set 508 can operate in parallel to simultaneously pattern the top and bottom wax layers on the photovoltaic structures, thus significantly improving the system throughput over the conventional photoresist-base masking approaches.

In addition to the system shown in FIG. 5A where the lasers move in order to create patterns on the wax layers, it is also possible to keep the lasers themselves stationary while steering the laser beams using mirrors. FIG. 5B shows an exemplary laser-wax-patterning system, according to an embodiment of the present invention. Laser-wax-patterning system 530 can include transparent platform 532 for supporting photovoltaic structures (e.g., photovoltaic structure 534), a number of lasers (e.g., lasers 536 and 538) for patterning the top wax layer, and a number of lasers (e.g., lasers 540 and 542) for patterning the bottom wax layer.

In addition, laser-wax-patterning system 530 can also include a number of mirror systems. More specifically, the output of each laser can be sent to a mirror system that can steer the laser beams. For example, outputs of lasers 536 and 538 are sent to mirror systems 544 and 546, respectively. A mirror system can include a number of movable mirrors. By adjusting the position and orientation of the mirrors, the laser beam can be steered to any desired location. For example, by adjusting mirrors of mirror system 544, the laser beam emitted by laser 536 can be steered to move along the direction of a desired busbar, creating a window corresponding to the desired busbar on the top wax layer of photovoltaic structure 534. After creating one window for a busbar, the laser beam can be steered to the location of the next busbar to create a window for the next busbar. The laser can be turned off or the laser beam can be blocked when the laser beam is steered from one busbar location to the next to avoid creating unwanted features on the wax layer. Similarly, by adjusting mirrors of mirror system 546, the laser beam emitted by laser 538 can be steered to move along the direction of a desired finger line, creating a window corresponding to the desired finger line. After creating one window for a finger line, the laser beam can be steered to the location of the next finger line to create a window for the next finger line.

Various techniques can be used to move the mirrors, including but are not limited to: using an electric motor or a galvanometer, using piezoelectric actuators, using magnetostrictive actuators, etc. Galvanometer mirrors, due to their built-in servo-control system, can achieve precise positioning at high speed. In some embodiments, a mirror system (e.g., mirror systems 544 and 546) can include a pair of galvanometers. In further embodiments, each galvanometer can be controlled to have a freely addressable motion. By pre-programming the galvanometer controls, the laser beam can be configured to create a desired grid pattern on the wax layer, with windows corresponding to both busbars and finger lines.

The lasers for patterning the bottom wax layer can be configured in a similar way to create a grid pattern on the bottom wax layer of photovoltaic structure 534.

In the example shown in FIG. 5B, lasers having different spot sizes can be used to create the busbars and finger lines separately. In practice, because the galvanometer can steer a laser beam at a high speed, it can also be possible to use one laser to create a grid pattern on the top or bottom wax layer. For example, to create a busbar pattern using a laser beam with a spot size comparable to the width of the finger line, one can configure the galvanometers in a way that the laser beam can scan multiple times along the busbar direction.

In addition, because the finger lines are typically parallel to each other, it can also be possible to use the same mirror system to steer multiple parallel laser beams in order to simultaneously create multiple finger line patterns. This arrangement can significantly improve throughput, because there might be tens of finger line patterns on each side of the photovoltaic structure.

In a mass production setting, the transparent platform supporting the photovoltaic structures can be part of the conveyor system that moves the photovoltaic structures. In some embodiments, the conveyor system can pause to allow the lasers to pattern the wax layers of a photovoltaic structure before moving to bring the next photovoltaic structure to position for patterning. In alternative embodiments, the conveyor can move continuously, and the steering of the laser beams can take consideration of the conveyor movements in order to create the desired plating patterns.

In addition to the configurations shown in FIGS. 5A-5B, where the photovoltaic structures are oriented horizontally and laser beams are shining on the surfaces of the photovoltaic structures from above and below, it can also be possible to arrange the photovoltaic structures vertically. FIG. 5C shows an exemplary laser-wax-patterning system, according to an embodiment of the present invention. Laser-wax-patterning system 560 can include wafer-holding jig 562 for holding photovoltaic structures (e.g., photovoltaic structure 564), first laser system 566, and second laser system 568.

Wafer-holding jig 562 can be configured to hold the photovoltaic structures in a vertical direction, thus exposing the wax coating on both surfaces of the photovoltaic structure. Various holding/mounting techniques can be used by wafer-holding jig 562. For example, wafer-holding jig 562 can include pre-cut slots for holding the photovoltaic structures, or wafer-holding jig 562 can include a frame and a number of spring-loaded pins for mounting the photovoltaic structures on the frame.

Laser systems 566 and 568 can include one or more lasers, and can also include one or more mirroring systems for steering the laser beams. Laser systems 566 and 568 can be similar to the lasers shown in FIG. 5A or the laser-mirror combined systems shown in FIG. 5B. Laser systems 566 and 568 are positioned on opposite sides of photovoltaic structure 564 and can be configured to each create a grid pattern on a corresponding wax coating. For example, laser system 566 can create a plating mask on one side of photovoltaic structure 564, and laser system 568 can create a plating mask on the opposite side of photovoltaic structure 564.

When the photovoltaic structures are held vertically, the laser beams can scan the surface of the wax coatings directly (instead of through a transparent platform) and the evaporated wax can escape easily. However, loading or mounting photovoltaic structures to vertical wafer-holding jig 562 can be much more difficult than placing them onto the horizontal platform.

Returning now to FIG. 4, after the wax layers on both sides of the photovoltaic structures are patterned, the photovoltaic structures can be sent to an electrolyte bath 408 for electroplating of the metallic grids. As discussed previously, the laser-created windows/grooves can expose the underlying metallic seed layer at desired locations, resulting in metallic ions being deposited at those locations. In some embodiments, to ensure high throughput, the photovoltaic structures with a wax plating mask on both surfaces can be carried by a moving cathode to move from one end of the electrolyte bath to the other end during plating. The photovoltaic structures can be attached to the moving cathode using custom-designed wafer-holding jigs, which can be similar to wafer-holding jig 562, and can hold the photovoltaic structures vertically. The custom-designed jig can also establish electrical connections to the exposed metallic seed layers of both surfaces, thus allowing simultaneous plating on both sides of the photovoltaic structures. It can also be possible to use the same wafer-holding jig for mask patterning and plating, thus eliminating the need to unload and load the photovoltaic structures between these two operations.

By controlling the plating time (e.g., by controlling the speed of the moving cathode), fabrication system 400 can control the thickness of the plated metallic layer. In some embodiments, the plated metallic layer can be at least 100 microns thick to ensure low resistivity of the grids. Photovoltaic structures emerging from electrolyte bath 408 are sent to rinsing station 410, which can rinse way any residual electrolyte solutions. Subsequent to rinsing, the photovoltaic structures are sent to hot water bath 412, which maintains a temperature greater than the melting point of the wax. The wax plating mask can then be removed by hot water bath 412. After mask removal, the photovoltaic structures can be again rinsed and dried, and can be ready for further fabrication.

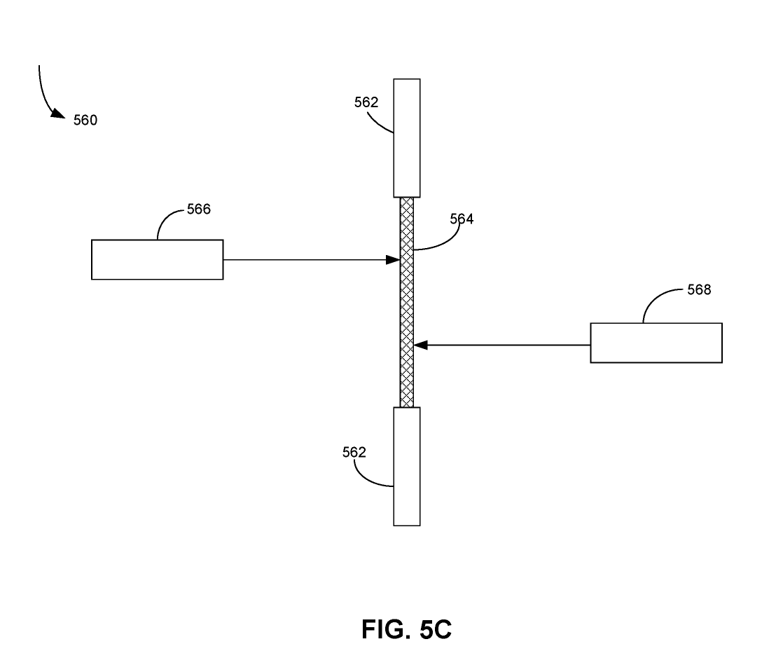

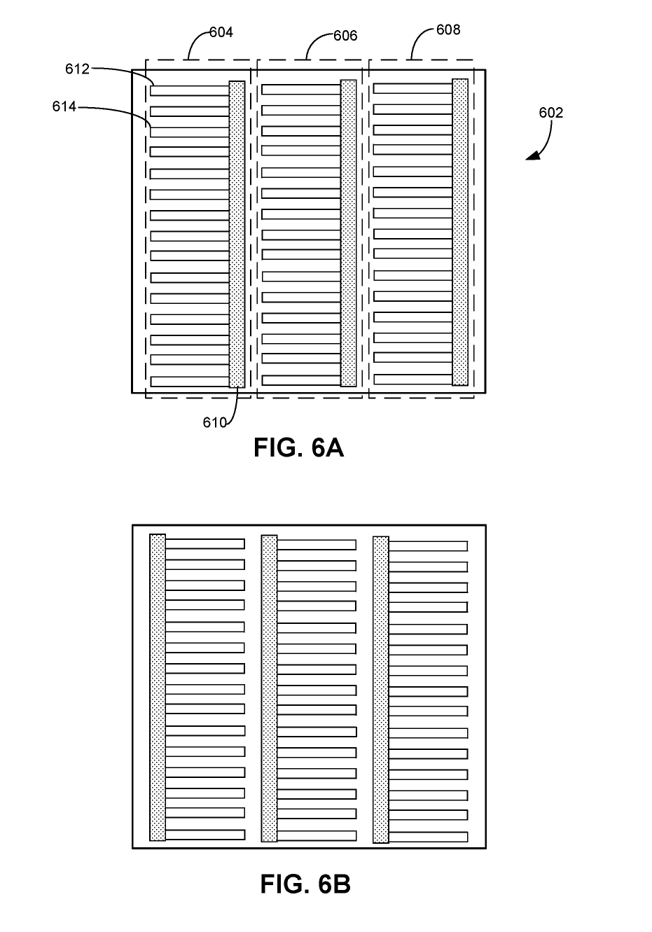

FIG. 6A shows an exemplary grid pattern formed on the front surface of a photovoltaic structure, according to one embodiment of the present invention. FIG. 6B shows an exemplary grid pattern formed on the back surface of a photovoltaic structure, according to one embodiment of the present invention. More specifically, each grid can include three sub-grids. For example, in FIG. 6A, grid 602 includes sub-grids 604, 606, and 608. Each sub-grid can include a busbar (which is located at an edge of the sub-grid) and a number of finger lines. For example, sub-grid 604 can include edge busbar 610, and a plurality of finger lines, such as finger lines 612 and 614.

This three sub-grid configuration allows photovoltaic structures of a standard size to be divided into three strips, and those strips can be edge-overlapped to form a serially connected string. A detailed description of the cascaded string of solar cell strips can be found in U.S. patent application Ser. No. 14/563,867, entitled “High Efficiency Solar Panel,” filed Dec. 8, 2014, the disclosure of which is incorporated herein by reference in its entirety. The sub-grids shown in FIG. 6B are similar to those shown in FIG. 6A, except that the edge busbar is located at the opposite edge of the corresponding sub-grid.

From FIGS. 6A and 6B, one can see that each side of the photovoltaic structure can include three identical sub-grid patterns, and each sub-grid can include a wider busbar and a number of thinner finger lines. To create a wax mask that corresponds to the grid pattern, the laser-wax-patterning system at each side of the photovoltaic structure can include at least three laser systems that can simultaneously create the three sub-grid patterns. Alternatively, one laser system can create the three sub-grid patterns consecutively. Because the width of the busbar is significantly larger than that of the finger lines, one may wish to use lasers having different spot sizes to separately create the busbar and finger line patterns. However, it is also possible to use laser beams with a smaller spot size (the diameter of which can be comparable to or smaller than the width of the finger lines) to create both the busbar and finger line patterns, especially when galvanometers are used to steer the laser beams. To create windows with a width that corresponds to the finger line width (e.g., between 20 and 100 micron), the spot size of the laser beam needs to be smaller than the finger line width. The fast response time of the galvanometers makes it possible to create larger features using laser beams having a smaller spot size. The advantage of the smaller spot size is that heat generated by the laser beams is focused onto a smaller area. Hence, lower power (hence lower cost) lasers can be used to create patterns on the wax layers.

Compared to the conventional photoresist-based process for creating the plating mask, this novel process has higher throughput, uses less expensive equipment (lasers can be much cheaper than lithography equipment), consumes cheaper material (wax is much cheaper than photoresist and can be recycled), and can be more environmentally friendly. Therefore, this novel process can be suitable for the large-scale manufacturing of photovoltaic structures. In addition to the aforementioned advantages, compared to the conventional approaches, this novel process can also provide flexibility in designing grid patterns. For example, if there is a change in the design of the grid patterns (e.g., the width and/or spacing of the finger lines can be changed), to create a corresponding photoresist-based plating mask, one may need to obtain a new optical mask for the photolithography process, which can be expensive. On the other hand, to create a corresponding wax-based plating mask, one only needs to reprogram the control of the lasers and/or the galvanometers. This makes this novel process also suitable for the smaller-scale fabrication required during the research and development phase, because there is no longer the need to make a new expensive optical mask each time the researcher implements a new grid design.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A fabrication method, comprising:
applying a wax coating on at least one surface of a multilayer photovoltaic structure, wherein the surface of the multilayer photovoltaic structure is electrically conductive; and
patterning the wax coating using one or more laser beams, wherein the patterned wax coating includes a plurality of openings that expose portions of the electrically conductive surface of the multilayer photovoltaic structure.

2. The method of claim 1, wherein applying the wax coating further comprises simultaneously applying the wax coating on both surfaces of the multilayer photovoltaic structure.

3. The method of claim 1, wherein applying the wax coating involves one of:
placing the multilayer photovoltaic structure in a hot wax bath;
applying a curtain-coating technique; and
applying a spin-coating technique.

4. The method of claim 1, wherein a thickness of the wax coating is between 100 and 500 microns.

5. The method of claim 1, wherein the one or more laser beams include a first laser beam having a first spot size for creating openings corresponding to busbars and a second laser beam having a second spot size for creating openings corresponding to finger lines, wherein the first spot size is greater than the second spot size.

6. The method of claim 1, wherein patterning the wax coating involves steering the one or more laser beams using mirrors.

7. The method of claim 7, wherein steering the one or more laser beams involves a galvanometer.

8. The method of claim 1, further comprising:
using the patterned wax coating as a plating mask to plate a metallic grid on the surface of the multilayer photovoltaic structure, wherein the plated metallic grid correspond to the openings in the wax coating.

9. The method of claim 8, further comprising:
subsequent to plating the metallic grid, removing the patterned wax coating using hot water.

10. The method of claim 1, wherein the electrically conductive surface of the multilayer photovoltaic structure comprises a metallic seed layer, and wherein the metallic seed layer is formed on a transparent conductive oxide layer using a physical vapor deposition technique.

11. A fabrication system, comprising:
a wax-coating tool configured to apply a wax coating on at least one surface of a multilayer photovoltaic structure, wherein the surface of the multilayer photovoltaic structure is electrically conductive; and
a laser-patterning tool configured to pattern the wax coating using one or more laser beams, wherein the patterned wax coating includes a plurality of openings that expose portions of the electrically conductive surface of the multilayer photovoltaic structure.

12. The system of claim 11, wherein the wax-coating tool is further configured to simultaneously apply the wax coating on both surfaces of the multilayer photovoltaic structure.

13. The system of claim 11, wherein the wax-coating tool includes one of:
a dip-coating tool;
a curtain-coating tool; and
a spin-coating tool.

14. The system of claim 11, wherein a thickness of the wax coating is between 100 and 500 microns.

15. The system of claim 11, wherein the one or more laser beams include a first laser beam having a first spot size for creating openings corresponding to busbars and a second laser beam having a second spot size for creating openings corresponding to finger lines, wherein the first spot size is greater than the second spot size.

16. The system of claim 11, wherein the laser-patterning tool further includes a mirror system configured to steer the one or more laser beams.

17. The system of claim 16, wherein the mirror system includes at least one galvanometer.

18. The system of claim 11, further comprising a plating tool configured to plate a metallic grid on the surface of the multilayer photovoltaic structure, using the patterned wax coating as a plating mask, wherein the plated metallic grid correspond to the openings in the wax coating.

19. The system of claim 18, further comprising a mask-removal tool configured to remove, using hot water, the patterned wax coating subsequent to the plating tool plating the metallic grid.

20. The system of claim 11, wherein the electrically conductive surface of the multilayer photovoltaic structure comprises a metallic seed layer, and wherein the metallic seed layer is formed on a transparent conductive oxide layer using a physical vapor deposition technique.
